(19) United States
(12) Patent Application Publication
(10) Pub. No.: US 2025/0087969 A1
(43) Pub. Date: Mar. 13, 2025

(54) Light-Emitting Device

(71) Applicant: Nippon Telegraph and Telephone Corporation, Tokyo (JP)

(72) Inventors: Yoshiho Maeda, Musashino-shi, Tokyo (JP); Koji Takeda, Musashino-shi, Tokyo (JP); Takuro Fujii, Musashino-shi, Tokyo (JP); Toru Segawa, Musashino-shi, Tokyo (JP); Shinji Matsuo, Musashino-shi, Tokyo (JP)

(21) Appl. No.: 18/721,574

(22) PCT Filed: Dec. 20, 2021
(86) PCT No.: PCT/JP2021/047027

§ 371 Date: Jun. 18, 2024

(51) Int. Cl. H01S 5/20; H01S 5/323

(52) U.S. Cl. CPC H01S 5/2022; H01S 5/2031; H01S 5/323

(57) ABSTRACT

A light-emitting device includes a waveguide-type light-emitting element formed on a cladding layer, a core formed on the cladding layer and constituting a port opposite to an output port of the light-emitting element, and a light absorption layer formed on the core in contact therewith. The core may be composed of a III-V compound semiconductor such as InP. The core is composed of a III-V compound semiconductor capable of guiding (transmitting) light (laser light) output from the light-emitting element. The light absorption layer is composed of a III-V compound semiconductor having a refractive index higher than that of the core, such as InGaAs. The III-V compound semiconductor having a higher refractive index has an absorption coefficient for light (light output from the light-emitting element) transmitted through the core.

### TECHNICAL FIELD

The present invention relates to a light-emitting device provided with a light-emitting element.

### BACKGROUND ART

Due to the explosive growth in the amount of network traffic associated with the spread of the Internet, optical fiber transmission continues to increase in speed and capacity. A semiconductor laser is used for a light-emitting device such as an optical transceiver used in optical communication, and has continued to develop as a light source device supporting optical fiber communication. For example, the light-emitting device is configured as shown in FIGS. 10A, 10B, and 10C. The light-emitting device includes a semiconductor laser 302 formed on a cladding layer 301, an output port 303 by a first core 305, and an unnecessary port 304 by a second core 306.

The semiconductor laser 302 includes a compound semiconductor layer 321 such as InP, and a core-shaped active layer 322 embedded in the compound semiconductor layer 321. In addition, an n semiconductor layer 323 and a p semiconductor layer 324 formed so as to sandwich the active layer 322 in a direction perpendicular to the waveguide direction are provided in an optical waveguide by the active layer 322. The n semiconductor layer 323 is composed of a compound semiconductor doped with an n-type impurity, and the p semiconductor layer 324 is composed of a compound semiconductor doped with a p-type impurity. A region of the compound semiconductor layer 321 in which the active layer 322 is embedded is non-doped. An n electrode 327 and a p electrode 328 are ohmic-connected to the n semiconductor layer 323 and the p semiconductor layer 324 via an n contact layer 325 and a p contact layer 326.

The semiconductor laser 302 thus constructed as described above is a semiconductor laser having a diffraction grating as a distributed Bragg reflection structure (resonator). Laser oscillation is obtained by injecting a current into the active layer 322 of the semiconductor laser 302 via the n electrode 327 and the p electrode 328. The laser beam generated by this laser oscillation is guided (output) to the output port 303 and the unnecessary port 304.

Thus, the light generated by the semiconductor laser is emitted from both ends of the semiconductor laser. In this main semiconductor laser, since light is generally taken out from one side (output port), light emitted from the side (unnecessary port) not used for taking light out is radiated into a space/optical integrated circuit as stray light, and a part of the light is returned into the semiconductor laser and reflected as light.

It is known that the occurrence of such stray light causes optical crosstalk in an optical integrated circuit and that the operation of the semiconductor laser becomes unstable due to the occurrence of reflected return light (see NPL 1).

For this reason, it is indispensable to reduce light emitted from unnecessary ports, i.e., to terminate the light, for the stable operation of the semiconductor laser. For such an optical termination, a technique has conventionally been used in which, as shown in FIG. 11, outgoing light from the unnecessary port 304 by a second core 306a is coupled to an optical waveguide 307 with a Si core 308 heavily doped to p-type, and the light is absorbed by free carrier absorption. The second core 306a is configured to become narrower as it moves away from the semiconductor laser 302, and the Si core 308 is configured to become narrower as it approaches the coupling section with the second core 306a. In addition, a method for optically wiring an optical waveguide constituting an unnecessary port in a spiral shape in a plan view and gradually releasing the optical waveguide to a space is used for optical termination.

### CITATION LIST

### Non Patent Literature

[NPL 1]S. Gomezl et al., “High coherence collapse of a hybrid III-V/Si semiconductor laser with a large quality factor,” Journal of Physics: Photonics, vol. 2, 025005, 2020.

### SUMMARY OF INVENTION

### Technical Problem

However, in the light absorption by free carrier absorption, in order to suppress the stray light or the like described above, the waveguide length of the optical waveguide constituting the optical termination becomes longer, resulting in a larger occupied area for the optical transceiver and hindering the miniaturization of the device. In order to couple the Si optical waveguide to the unnecessary port, optical reflection is generated during the coupling process, and the reflected light become a return light to the semiconductor laser, which is a problem.

The present invention has been made to solve the above problems, and an object of the present invention is to reduce light output to an unnecessary port without interfering with miniaturization.

### Solution to Problem

A light-emitting device according to the present invention includes a waveguide-type light-emitting element formed on a cladding layer, a core formed on the cladding layer and composed of a III-V compound semiconductor constituting a port opposite to an output port of the light-emitting element, and a light absorption layer formed on the core in contact therewith.

### Advantageous Effects of Invention

As described above, according to the present invention, since the light absorption layer composed of the III-V compound semiconductor having a refractive index higher than that of the core is provided on the core constituting the port opposite to the output port, the light that is output to the unnecessary port can be reduced without interfering with miniaturization.

### BRIEF DESCRIPTION OF DRAWINGS

FIG. 1A is a plan view showing a configuration of a light-emitting device according to an embodiment of the present invention.

FIG. 1B is a cross-sectional view showing a partial configuration of the light-emitting device according to an embodiment of the present invention.

FIG. 1C is a cross-sectional view showing a partial configuration of the light-emitting device according to an embodiment of the present invention.

FIG. 2 is a plan view showing a configuration of another light-emitting device according to an embodiment of the present invention.

FIG. 3 is a plan view showing a configuration of another light-emitting device according to an embodiment of the present invention.

FIG. 4A is a plan view showing a configuration of another light-emitting device according to an embodiment of the present invention.

FIG. 4B is a cross-sectional view showing a partial configuration of another light-emitting device according to an embodiment of the present invention.

FIG. 5A is an explanatory diagram for explaining conditions used for calculating the amounts of transmitted and reflected outgoing light to a conventional unnecessary port.

FIG. 5B is an explanatory diagram for explaining conditions used for calculating the amounts of transmitted and reflected outgoing light to a conventional unnecessary port.

FIG. 6A is an explanatory diagram for explaining conditions used for calculating the amounts of transmitted and reflected outgoing light to an optical terminator constituting a light-emitting device according to an embodiment.

FIG. 6B is an explanatory diagram for explaining conditions used for calculating the amounts of transmitted and reflected outgoing light to an optical terminator constituting a light-emitting device according to an embodiment.

FIG. 7A is an explanatory diagram for explaining conditions used for calculating the amounts of transmitted and reflected outgoing light to a conventional optical terminator.

FIG. 7B is an explanatory diagram for explaining conditions used for calculating the amounts of transmitted and reflected outgoing light to a conventional optical terminator.

FIG. 8A is a distribution diagram of the amounts of transmitted and reflected outgoing light to the conventional unnecessary port.

FIG. 8B is a distribution diagram of the amounts of transmitted and reflected outgoing light to the optical terminator constituting the light-emitting device according to the embodiment.

FIG. 8C is a distribution diagram of the amounts of transmitted and reflected outgoing light to the conventional optical terminator.

FIG. 9 is a characteristic diagram showing the amounts of transmitted and reflected outgoing light in each configuration.

FIG. 10A is a plan view showing a configuration of a conventional light-emitting device.

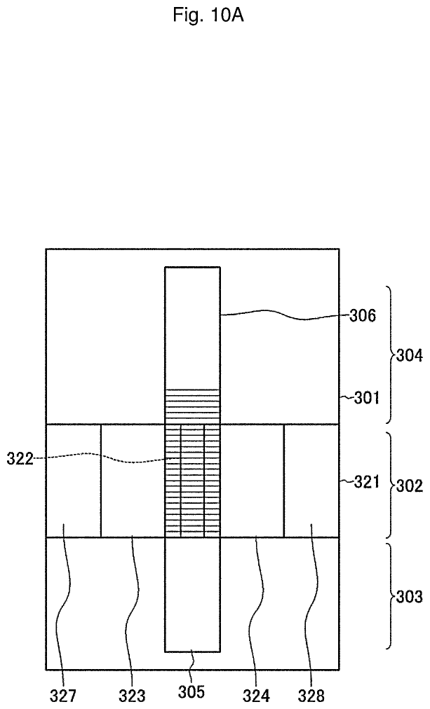

FIG. 10B is a cross-sectional view showing a partial configuration of the conventional light-emitting device.

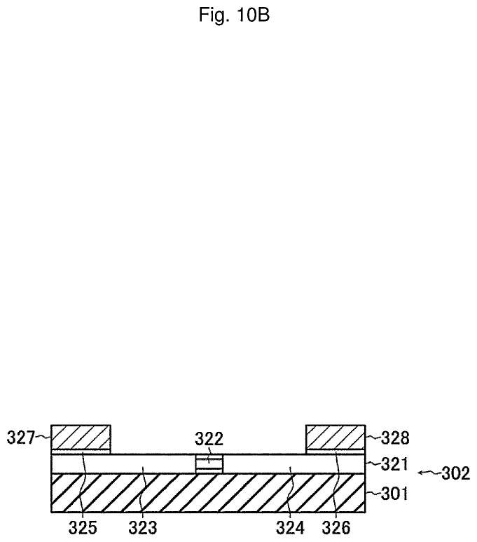

FIG. 10C is a cross-sectional view showing a partial configuration of the conventional light-emitting device.

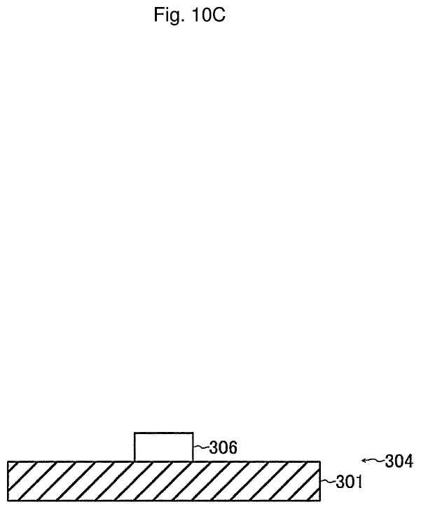

FIG. 11 is a plan view showing a configuration of the conventional light-emitting device.

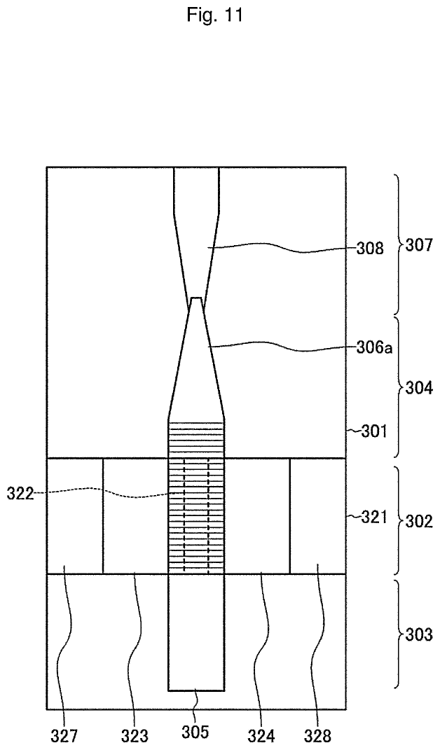

### DESCRIPTION OF EMBODIMENTS

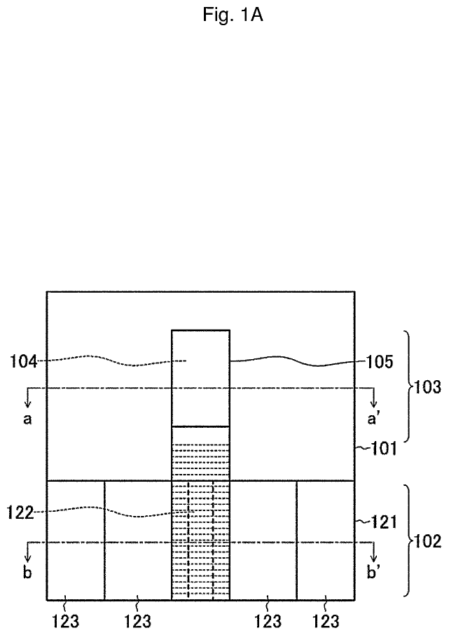

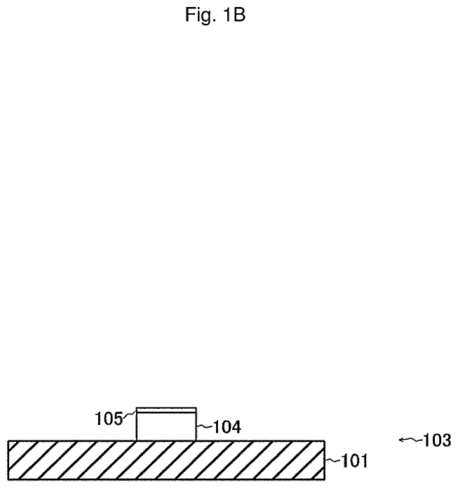

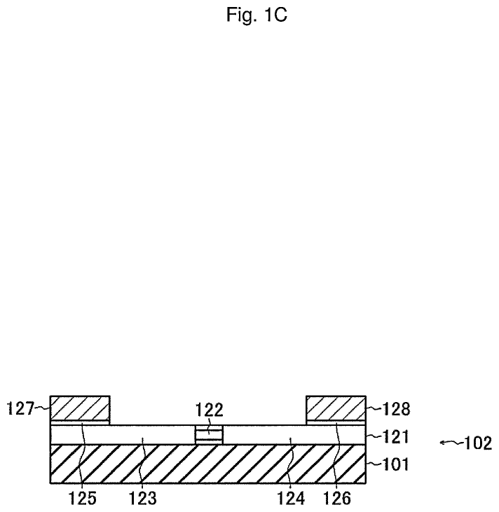

Hereinafter, a light-emitting device according to an embodiment of the present invention will be described with reference to FIGS. 1A, 1B, and 1C. Note that FIG. 1B shows a cross section taken along line aa′ of FIG. 1A. FIG. 1C illustrates a cross section taken along a line bb′ of FIG. 1A.

This light-emitting device includes a waveguide-type light-emitting element 102 formed on a cladding layer 101, a core 104 formed on the cladding layer 101 and constituting a port 103 opposite to an output port of the light-emitting element 102, and a light absorption layer 105 formed on the core 104 in contact therewith.

The cladding layer 101 can be composed of an insulating material such as silicon oxide, for example. The core 104 may be constituted by a III-V compound semiconductor such as InP. The core 104 is composed of a III-V compound semiconductor capable of guiding (transmitting) light (laser light) output from the light-emitting element 102.

The light absorption layer 105 is composed of a III-V compound semiconductor having a refractive index higher than that of the core 104, such as InGaAs. The III-V compound semiconductor having a higher refractive index has an absorption coefficient for light (light output from the light-emitting element 102) transmitted through the core 104. In a region where the light absorption layer 105 is formed, the core 104 and the light absorption layer 105 have the same shape in plan view.

In FIGS. 1B and 1C, the cladding above the light-emitting element 102, the core 104, and the light absorption layer 105 is omitted, but the upper cladding can be composed of an insulating material such as silicon oxide, for example, as in the cladding layer 101. The upper cladding can also be air.

The light-emitting element 102 is, for example, a well-known lateral current injection type semiconductor laser, and includes a core-shaped active layer 122 embedded in a compound semiconductor layer 121 such as InP. In addition, an n semiconductor layer 123 and a p semiconductor layer 124 formed so as to sandwich the active layer 122 in a direction perpendicular to the waveguide direction are provided in an optical waveguide by the active layer 122. In this example, the n semiconductor layer 123 and the p semiconductor layer 124 are disposed so as to sandwich the active layer 122 in a direction parallel to the plane of the cladding layer 101 (lateral current injection type).

The n semiconductor layer 123 is composed of a III-V compound semiconductor (InP) doped with an n-type impurity, and the p semiconductor layer 124 is composed of a III-V compound semiconductor (InP) doped with a p-type impurity. These are formed by doping the compound semiconductor layer 121 with corresponding impurities. The region of the compound semiconductor layer 121 in which the active layer 122 is buried is non-doped.

An n electrode 127 and a p electrode 128 are ohmic-connected to the n semiconductor layer 123 and the p semiconductor layer 124 via an n contact layer 125 and a p contact layer 126. The n contact layer 125 and the p contact layer 126 are composed of a III-V compound semiconductor (InGaAs) doped with a corresponding impurity at a high concentration. The light-emitting element 102 thus configured as described above is a semiconductor laser having the diffraction grating formed on the active layer 122 as a distributed Bragg reflection structure.

Laser oscillation is obtained by injecting a current into the active layer 122 of the light-emitting element 102 constituting the semiconductor laser, via the n electrode 127 and the p electrode 128. The laser beam generated by the laser oscillation is guided (output) to an output port (not shown) and a port 103 formed by the core 104. The port 103 is generally called an unnecessary port, but in the embodiment, the port 103 serves as an optical terminator.

Although the light-emitting element 102 has a so-called lateral current injection type current injection structure in the above description, the present invention is not limited thereto; a vertical current injection type current injection structure can be obtained.

According to the embodiment, the light emitted to the port 103 called an unnecessary port is mode-coupled to the light absorption layer 105 formed on the core 104, and propagates while being absorbed by the light absorption layer 105. As a result, reflection to the light-emitting element 102 and stray light into the optical integrated circuit can be reduced. For example, since InGaAs used as a contact layer of an InP-based semiconductor laser constituting the light-emitting element 102 has a high absorption coefficient in a communication wavelength band, the light to be output can be reduced without increasing the length of the port 103.

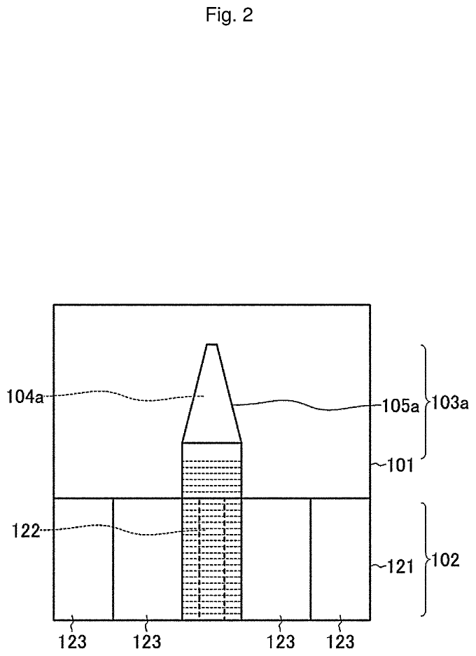

As shown in FIG. 2, a port 103a can be composed of a core 104a whose width becomes narrower as it moves away from the light-emitting element 102 in the waveguide direction. In this case, a light absorption layer 105a formed on the core 104a in contact therewith can also be made to become narrower as it moves away from the light-emitting element 102 in the waveguide direction.

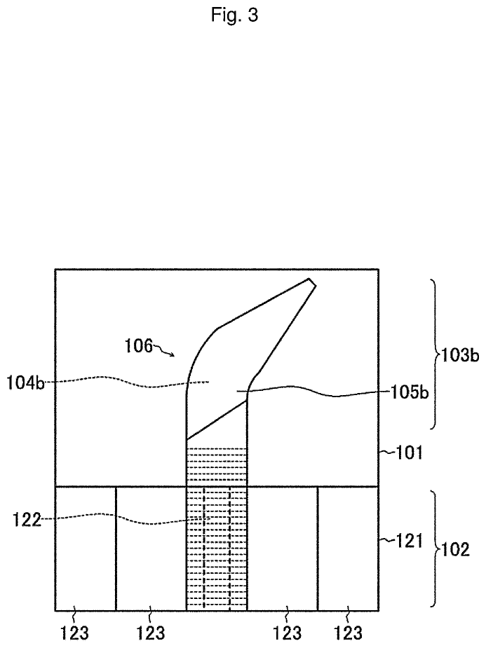

Further, as shown in FIG. 3, a port 103b can be constituted by the core 104b and the light absorption layer 105b in a state where a bent portion 106 is provided. The core 104b and the light absorption layer 105b change the waveguide direction at the bent portion 106. In this example, the waveguide direction of the core 104b and the light absorption layer 105b is changed to the right in a plan view at the bent portion 106.

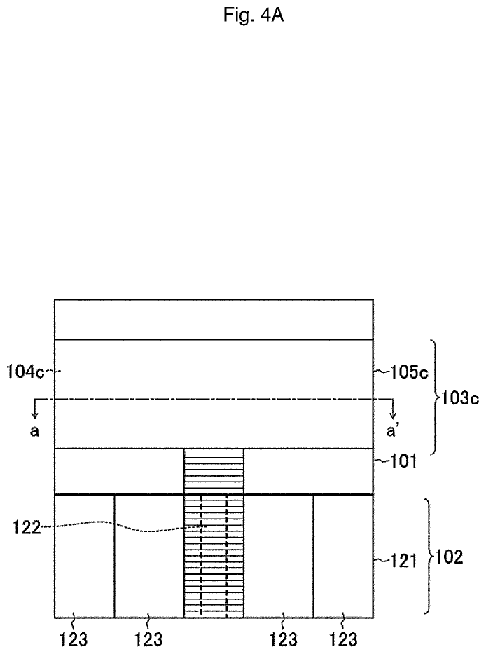

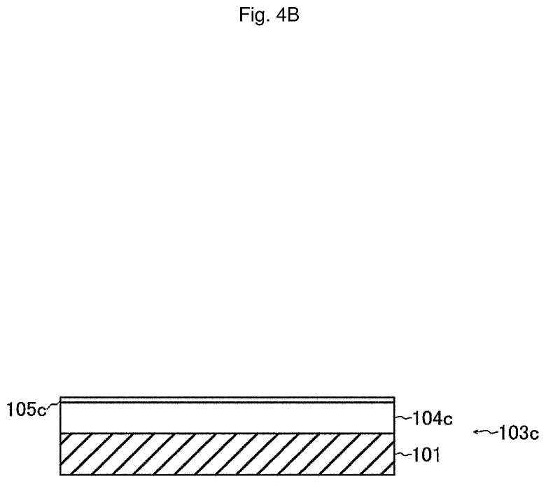

Further, as shown in FIGS. 4A and 4B, a port 103c can be composed of a core 104c and a light absorption layer 105c which have substantially the same width as the light-emitting element 102. For example, the core 104c has the same width as the compound semiconductor layer 121. Note that FIG. 4B shows a cross section of line aa′ of FIG. 4A.

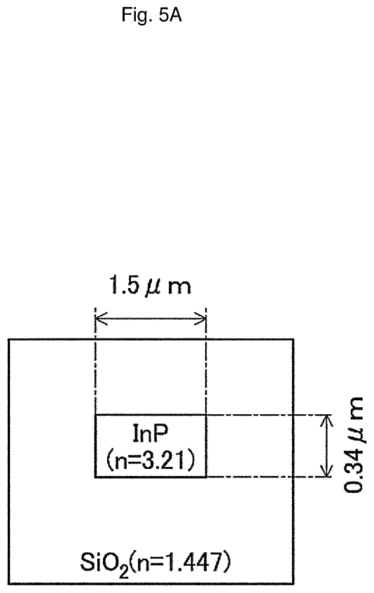

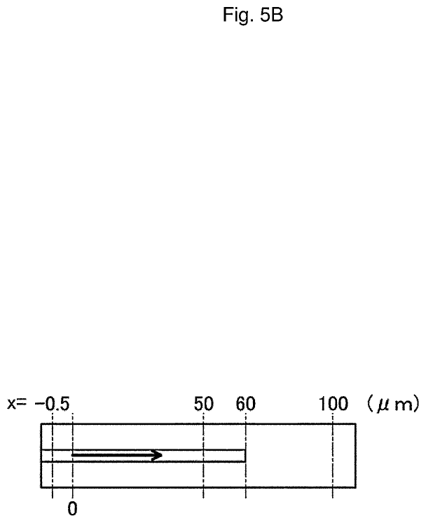

Next, a simulation result of the amounts of transmitted and reflected outgoing light to the unnecessary port constituting the optical terminator will be described. In this simulation, first, in a conventional configuration, as shown in FIG. 5A, the optical waveguide of the unnecessary port consists of a core made of InP and a cladding made of SiO₂, and the cross-sectional shape of the core is 1.5 μm in width and 0.34 μm in thickness.

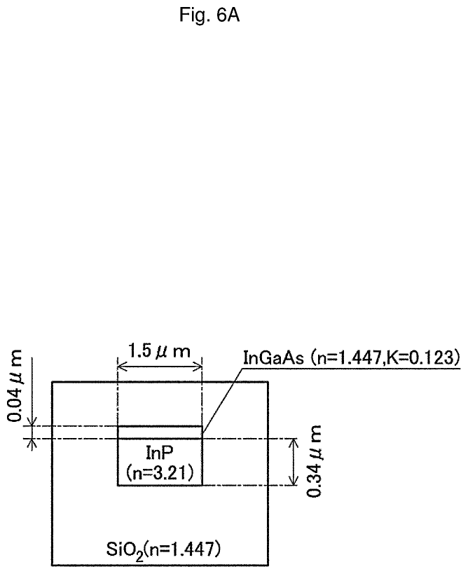

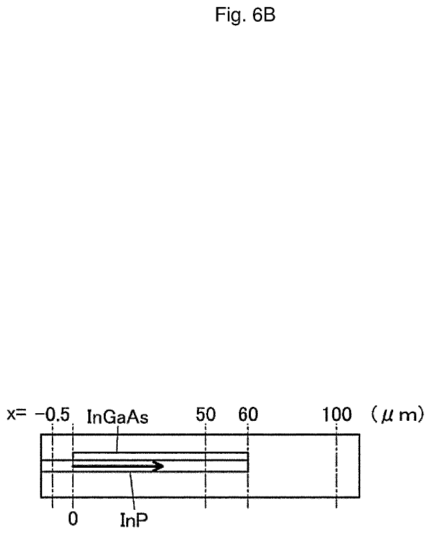

In a configuration according to an embodiment, as shown in FIG. 6A, the optical waveguide of the optical terminator (unnecessary port) consists of a core made of InP, an optical absorption layer of InGaAs formed on the top surface of the core, and a cladding made of SiO₂, the cross-sectional shape of the core is 1.5 μm in width and 0.34 μm in thickness, and the cross-sectional shape of the light absorption layer is 1.5 μm in width and 0.05 μm in thickness.

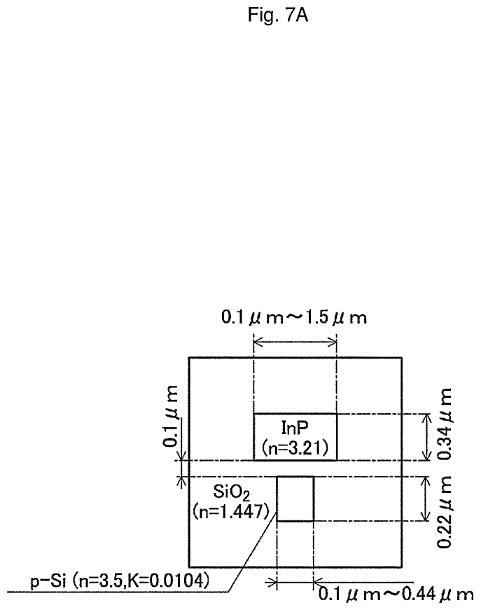

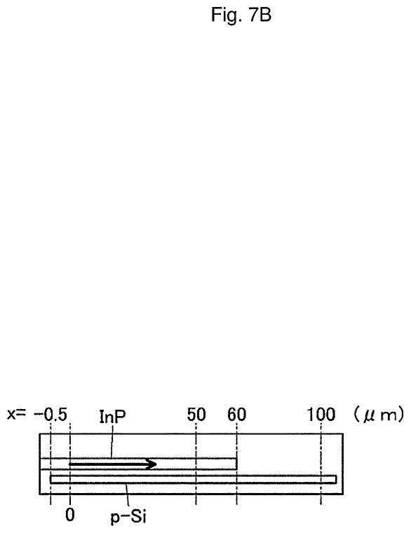

As a comparison, as shown in FIG. 7A, the optical terminator (unnecessary port) was composed of a core made of InP, a Si core disposed at the bottom of the core, and a cladding made of SiO₂, the cross-sectional shape of the core was 0.1 to 1.5 μm in width and 0.34 μm in thickness, the cross-sectional shape of the Si core was 0.1 to 0.44 μm and 0.22 μm in thickness, and the Si core was doped to p-type at a high concentration.

Also, in any configuration, as shown in FIGS. 5B, 6B, and 7B, the position x=0 μm in the waveguide direction was used as the light incident position, x=−5.0 μm as the reflectance monitor position, x=−50 μm as the transmittance monitor position, and x=100 μm as the stray light monitor position. The position x=60 μm in the waveguide direction is the waveguide end.

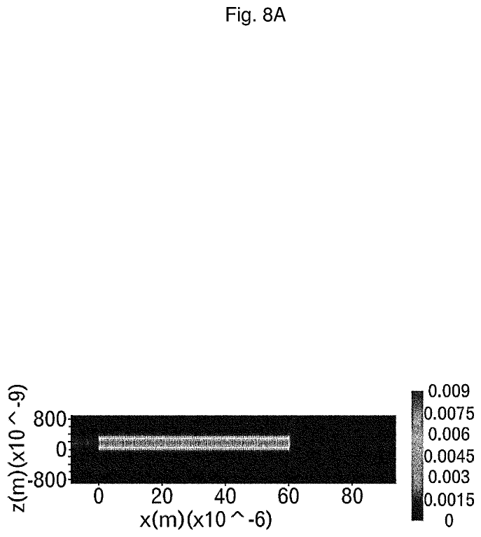

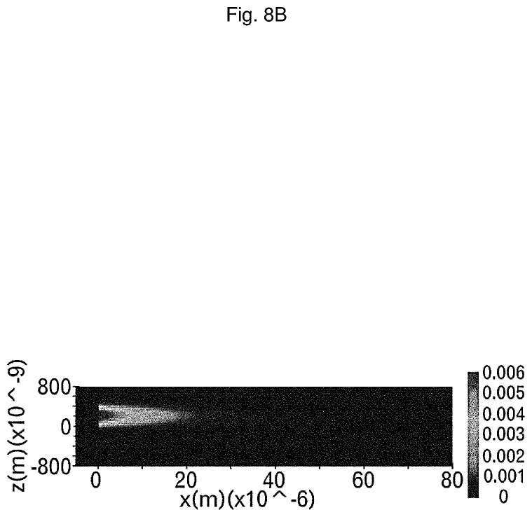

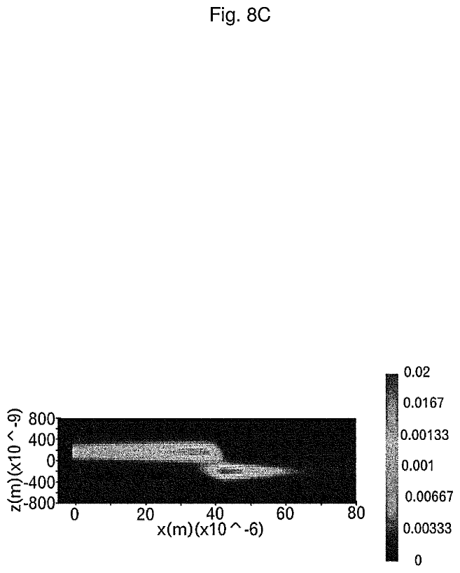

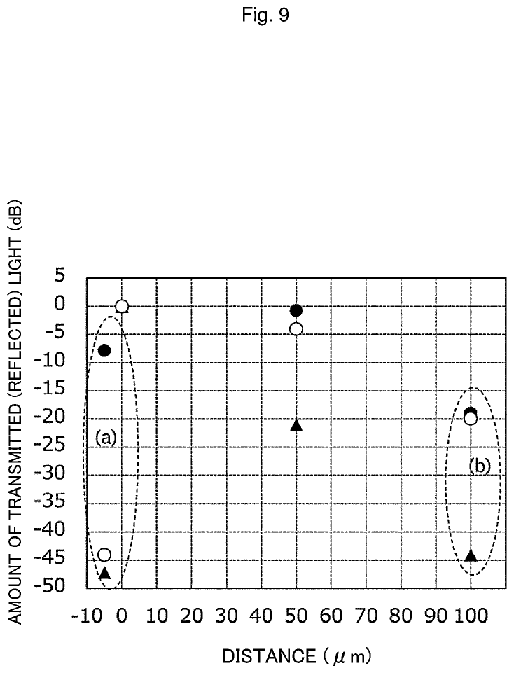

The distribution of the amounts of transmitted and reflected outgoing light to the conventional unnecessary port under the condition shown in FIG. 5A is shown in FIG. 8A. The distribution of the amounts of transmitted and reflected outgoing light to the optical terminator in the configuration according to the embodiment under the condition shown in FIG. 6A is shown in FIG. 8B. The distribution of the amounts of transmitted and reflected outgoing light to the optical terminator equipped with the conventional Si core under the condition shown in FIG. 7A is shown in FIG. 8C. FIG. 9 shows the results obtained by summarizing these components. In FIG. 9, a white circle indicates the states of the amounts of transmitted and reflected outgoing light to the conventional unnecessary port, a black circle indicates the states of the amounts of transmitted and reflected outgoing light to the optical terminator of the configuration according to the embodiment, and a black triangle indicates the states of the amounts of transmitted and reflected outgoing light to the optical terminator having the conventional Si core. In FIG. 9, (a) represents the amount of reflected outgoing light, and (b) represents the amount of stray light.

As is apparent from these results, the amount of reflected outgoing light is reduced in the optical terminator having the configuration according to the embodiment. In this example, the amount of reflected outgoing light is reduced by 40 dB or more. Moreover, it is understood that the optical terminator having the structure according to the embodiment can be reduced in size to a half or less in total length as compared with the case of using a Si core doped to a p-type at a high concentration.

As described above, according to the present invention, since the light absorption layer made of the III-V compound semiconductor having a refractive index higher than that of the core is provided on the core constituting the port opposite to the output port, the light to be output to the unnecessary port can be reduced.

Note that it is clear that the present invention is not limited to the embodiments described above and within the technical concept of the present invention and many modifications and combinations can be implemented by those skilled in the art.

### REFERENCE SIGNS LIST

101 Cladding layer
102 Light-emitting element
103 Port
104 Core
105 Light absorption layer
121 Compound semiconductor layer
122 Active layer
123 n semiconductor layer
124 p semiconductor layer
125 n contact layer
126 p contact layer
127 n electrode
128 p electrode

1. A light-emitting device, comprising:
a waveguide-type light-emitting element formed on a cladding layer;
a core formed on the cladding layer and composed of a III-V compound semiconductor constituting a port opposite to an output port of the light-emitting element; and
a light absorption layer that is composed of a III-V compound semiconductor having a refractive index higher than that of the core and is formed on the core in contact therewith.

2. The light-emitting device according to claim 1,
wherein in a region where the light absorption layer is formed, the core and the light absorption layer have the same shape in a plan view.

3. The light-emitting device according to claim 2,
wherein the core becomes narrower as the core moves away from the light-emitting element in a waveguide direction.

4. The light-emitting device according to claim 2,
wherein the core includes a bent portion.

5. The light-emitting device according to claim 2,
wherein the core has substantially the same width as the light-emitting element.

6. The light-emitting device according to claim 1,
wherein the core is made of InP, and the light absorption layer is made of InGaAs.

7. The light-emitting device according to claim 3,
wherein the core includes a bent portion.

8. The light-emitting device according to claim 2,
wherein the core is made of InP, and the light absorption layer is made of InGaAs.

9. The light-emitting device according to claim 3,
wherein the core is made of InP, and the light absorption layer is made of InGaAs.

10. The light-emitting device according to claim 4,
wherein the core is made of InP, and the light absorption layer is made of InGaAs.

11. The light-emitting device according to claim 5,
wherein the core is made of InP, and the light absorption layer is made of InGaAs.
